(19) United States
(12) Patent Application Publication
(10) Pub. No.: US 2011/0108881 A1
(43) Pub. Date: May 12, 2011

(54) METHOD FOR MANUFACTURING LIGHT-EMITTING DIODE

(75) Inventor: Tzu-Yu Tang, Taipei (TW)

(73) Assignee: EVERLIGHT ELECTRONICS CO., LTD., Taipei (TW)

(21) Appl. No.: 12/703,743

(22) Filed: Feb. 10, 2010

(30) Foreign Application Priority Data
Nov. 6, 2009 (TW) 98137857

(51) Int. Cl. H01L 33/00; H01L 21/30

(52) U.S. Cl. 257/103; 438/26; 257/E33.075; 257/E21.211

(57) ABSTRACT

A semiconductor structure is first provided. The semiconductor structure includes a sapphire substrate and a semiconductor light-emitting layer. A first surface of the semiconductor light-emitting layer covers and contacts with the sapphire substrate. Then, the semiconductor structure is fixed on a supported base. The sapphire substrate is further removed from the semiconductor structure. After that, a high heat-conductive layer is formed on the first surface of the semiconductor light-emitting layer to form a light-emitting diode. Finally, the supported base is separated from the light-emitting diode.

### CROSS-REFERENCE TO RELATED APPLICATION

This application claims the priority benefit of Taiwan application serial no. 98137857, filed Nov. 6, 2009. The entirety of the above-mentioned patent application is hereby incorporated by reference herein and made a part of specification.

### BACKGROUND OF THE INVENTION

1. Field of the Invention

The present invention relates to a light emitting device and manufacturing method thereof. In particular, the present invention relates to a light-emitting diode (LED) and manufacturing method thereof.

2. Description of Related Art

Due to advantages of low power consumption, low driving voltage, long lifetime and adherence to environmental concerns, LEDs have been extensively applied in illumination apparatuses and displays. If the aforementioned LEDs are applied in the illumination apparatus, the better brightness and light-emitting efficiency of the illumination apparatus can be generated to compare with the conventional light bulb. If the LEDs are applied in the display, the thickness of the display can be reduced to make the display thinner.

At present, the main structure of the common LED at least includes a substrate and a semiconductor light-emitting layer located on the substrate. The semiconductor light-emitting layer at least a P-type semiconductor layer and a N-type semiconductor layer. The substrate, in general, is a sapphire substrate. The crystal shape of the formed semiconductor light-emitting layer can meet the requirements of LED in application due to the sapphire substrate. Therefore the LED mostly adopts the sapphire substrate as the substrate in industry. Afterwards, since the sapphire substrate is a material with poor heat conductibility, the LED has a poor heat dissipation efficiency and the overall LED performance is further affect when the sapphire substrate is applied in the high power LED. For these reasons, how to improve the heat dissipation of the LED has been one of the issues that the manufacturers in this field need to be solved.

### SUMMARY OF THE INVENTION

The present invention provides a manufacturing method of a light-emitting diode (LED).

According to one embodiment of the present invention, a manufacturing method of a light-emitting diode (LED) is provided. Firstly, a semiconductor structure is provided, wherein the semiconductor structure has a sapphire substrate and a semiconductor light-emitting layer. A first surface of the semiconductor light-emitting layer covers and contacts with the sapphire substrate. Next, the semiconductor structure as described above is fixed on a supported base. After that, the sapphire substrate of the semiconductor structure is removed. Afterwards, a high heat-conductive layer is formed on the first surface of the aforementioned semiconductor light-emitting layer. Finally, the supported base is further removed.

According to another embodiment of the present invention, a manufacturing method of a light-emitting diode (LED) is provided. Firstly, a semiconductor structure is provided, wherein the semiconductor structure has a sapphire substrate and a semiconductor light-emitting layer. A surface of the semiconductor light-emitting layer covers and contacts with the sapphire substrate. Next, the semiconductor structure as described above is fixed on a supported base. Then, the aforementioned sapphire substrate is grinded so that a thickness of the sapphire substrate is between 0 micrometer to 50 micrometers. Afterwards, a high heat-conductive layer is formed on the surface of the grinded sapphire substrate. Finally, the supported base is removed.

According to still another embodiment of the present invention, a manufacturing method of a light-emitting diode (LED) is provided. A substrate is provided at first. Then, a diamond film is formed on the substrate. Finally, a semiconductor light-emitting layer is formed on the diamond film, wherein the semiconductor light-emitting layer comprises a N-type semiconductor layer and a P-type semiconductor layer, and the N-type semiconductor layer and the P-type semiconductor layer are stacked on the diamond film.

According to yet another embodiment of the present invention, a light-emitting diode (LED) is provided. The LED includes a diamond film substrate and a semiconductor light-emitting layer. The semiconductor light-emitting layer is located on the diamond film substrate, wherein the semiconductor light-emitting layer comprises a N-type semiconductor layer and a P-type semiconductor layer, and the N-type semiconductor layer or the P-type semiconductor layer contacts the diamond film substrate.

According to yet another embodiment of the present invention, a light-emitting diode (LED) is provided. The LED includes a sapphire substrate, a semiconductor light-emitting layer and a diamond film. The thickness of the sapphire substrate is between 0 micrometer to 50 micrometers. The semiconductor light-emitting layer is located on the sapphire substrate, wherein the semiconductor light-emitting layer comprises a N-type semiconductor layer and a P-type semiconductor layer, and the N-type semiconductor layer or the P-type semiconductor layer contacts the sapphire substrate. The diamond film is located on a surface of the semiconductor light-emitting layer which is opposite to the sapphire substrate.

In the aforesaid embodiment, the LED and manufacturing method thereof can enhance the heat dissipation efficiency of the LED by changing the thickness of the sapphire substrate and collocating with the high heat-conductive layer.

### BRIEF DESCRIPTION OF THE DRAWINGS

In order to make the above and other objects, features and advantages of the present invention more comprehensible, several embodiments accompanied with figures are described in detail below.

FIGS. 1A-1D are schematic cross-sectional flowcharts illustrating a manufacturing process of a light-emitting (LED) diode according to an embodiment of the present invention.

FIG. 2 is a schematic cross-sectional view depicting a light-emitting diode (LED) according to another embodiment of the present invention.

FIGS. 3A-3C are schematic cross-sectional flowcharts illustrating a manufacturing process of a light-emitting (LED) diode according to another embodiment of the present invention.

### DESCRIPTION OF EMBODIMENTS

### First Embodiment

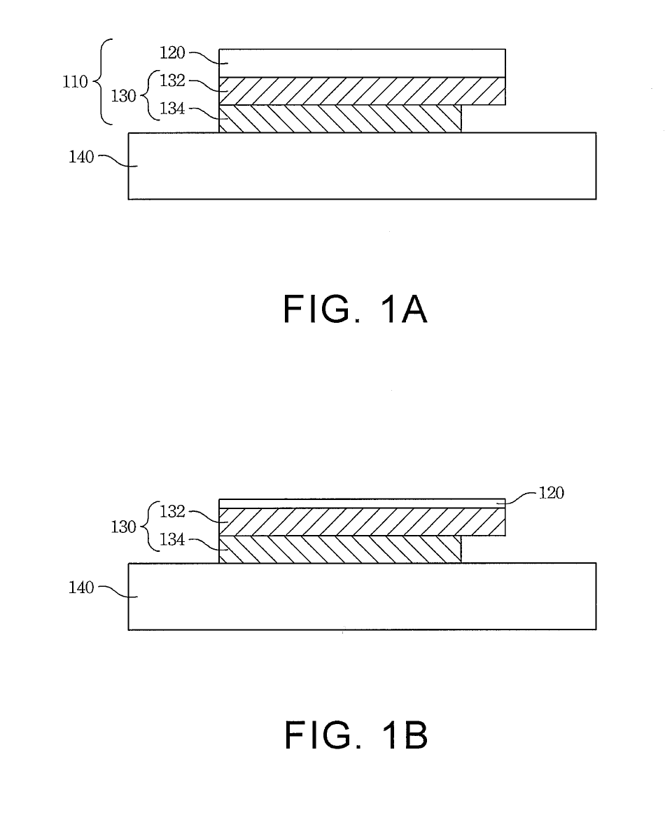

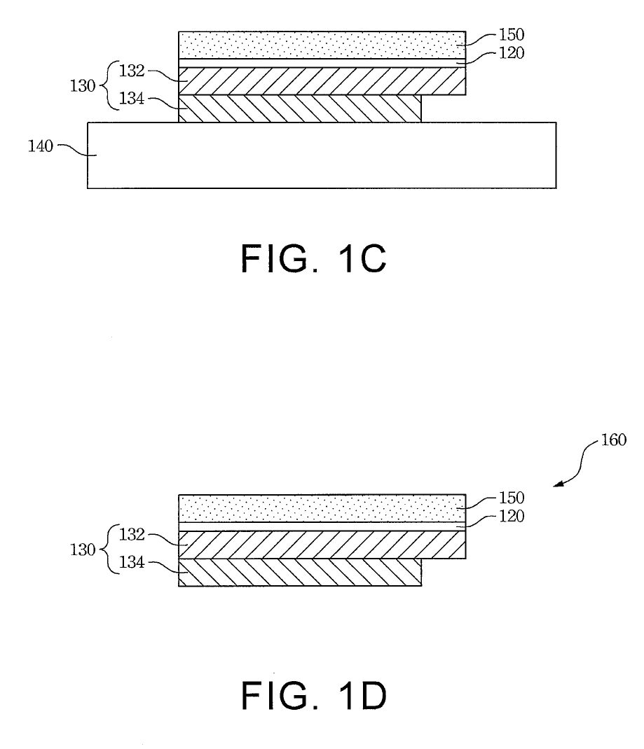

FIGS. 1A-1D are schematic cross-sectional flowcharts illustrating a manufacturing process of a light-emitting (LED) diode according to an embodiment of the present invention. In FIG. 1A, the semiconductor structure 110 is fixed on the supported base 140 as first, wherein the method for fixing can be, but not limited to, an adhesive bonding. The semiconductor structure 110 includes a sapphire substrate 120 and a semiconductor light-emitting layer 130, wherein a surface of the semiconductor light-emitting layer 130 covers and contacts with the sapphire substrate 120.

The aforementioned semiconductor light-emitting layer 130 at least includes a P-type semiconductor layer 132 and a N-type semiconductor layer 134, wherein the P-type semiconductor layer 132 and the N-type semiconductor layer 134 are stacked on the sapphire substrate 120. Herein, the position of the P-type semiconductor layer 132 and the N-type semiconductor layer 134 can be interchanged. The semiconductor light-emitting layer 130 may also be other feasible structure, for example, a multiple quantum well (MQW) material layer (not shown) is disposed between the P-type semiconductor layer 132 and the N-type semiconductor layer 134. The structure of the aforementioned semiconductor light-emitting layer 130 in the present invention is not limited to the one disclosed by the foregoing embodiments.

The material of the aforementioned P-type semiconductor layer 132 and the aforementioned N-type semiconductor layer 134 are constituted mainly by group III-V compounds. The main material of the P-type semiconductor layer 132 and the N-type semiconductor layer 134 is, for example, gallium nitride (GaN), aluminum gallium nitride (AlGaN), indium gallium nitride (InGaN), gallium arsenide (GaAs), gallium phosphide (GaP), aluminum gallium arsenide (AlGaAs), aluminum indium gallium phosphida (AlInGaP), zinc selenide (ZnSe) and silicon carbide (SiC).

Referring to FIG. 1B, after fixing the semiconductor structure 110, the sapphire substrate 120 is further grinded so that a thickness of the sapphire substrate 120 is between 0 micrometer to 50 micrometers or the sapphire substrate 120 is removed (not shown). The method of grinding can be, for example, an etching process or a laser ablation process.

Next, referring to FIG. 1C, a high heat-conductive layer 150 is formed on the grinded sapphire substrate 120. The high heat-conductive layer 150 can be a film with a coefficient of thermal conductivity larger than 2 W/cm.k, such as a diamond film or a diamond-like film. If the high heat-conductive layer 150 is the diamond film, the step of forming can be a chemical vapor deposition process, a physical vapor deposition process and so forth. The heat generated by semiconductor light-emitting layer 130 can be transmitted effectively by grinding the aforementioned sapphire substrate 120 and forming the high heat-conductive layer 150 on the sapphire substrate 120.

The sapphire substrate 120 can also be completely removed in the aforementioned step of grinding the sapphire substrate 120. The high heat-conductive layer can directly form on the semiconductor light-emitting layer if the sapphire substrate is completely removed (not shown). Since the high heat-conductive layer directly contacts with the semiconductor light-emitting layer, the heat generated by semiconductor light-emitting layer can be transmitted effectively.

The supported base 140 is further removed after forming the high heat-conductive layer 150. The fabrication of the LED 160 has been completed as illustrated in FIG. 1D. Herein, the thickness of the sapphire substrate 120 in the LED 160 is between 0 micrometer to 50 micrometers, and the diamond film 150 is located on a surface of the semiconductor light-emitting layer 130 which is opposite to the sapphire substrate 120.

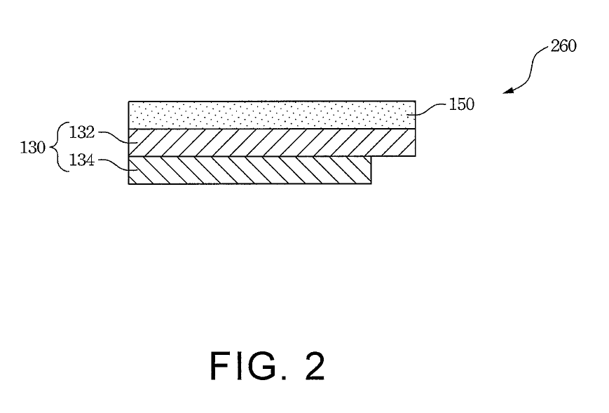

The cross-sectional view of the completed LED can refer to FIG. 2 if the step of grinding adopts the method by removing the sapphire substrate 120 completely.

The high heat-conductive layer 150 of the LED 260 directly contacts the semiconductor light-emitting layer 130 as shown in FIG. 2.

The heat dissipation efficiency of the LED 260 can be improved by the high heat-conductive layer 150 directly contacts with the semiconductor light-emitting layer 130.

### Second Embodiment

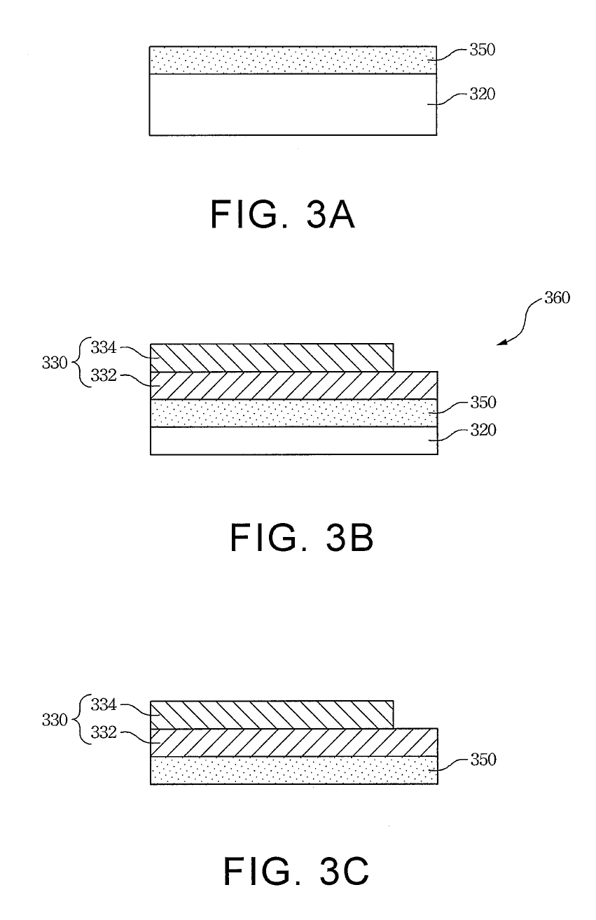

FIGS. 3A-3C are schematic cross-sectional flowcharts illustrating a manufacturing process of a light-emitting (LED) diode according to another embodiment of the present invention. Referring to FIG. 3A, a diamond film 350 is formed on the substrate 320 at first. The substrate 320 can be, for example, silicon substrate, aluminum oxide substrate, silicon nitride substrate, sapphire substrate or silicon carbide substrate.

Thereafter, referring to FIG. 3B, the semiconductor light-emitting layer 330 is formed on the diamond film 350 to form a LED 360. The aforementioned semiconductor light-emitting layer 330 at least includes a P-type semiconductor layer 332 and a N-type semiconductor layer 334, wherein the P-type semiconductor layer 332 and the N-type semiconductor layer 334 are stacked on the sapphire substrate 350. Herein, the position of the P-type semiconductor layer 332 and the N-type semiconductor layer 334 can be interchanged.

The aforementioned semiconductor light-emitting layer 330 can be formed on the diamond film 350 by crystallizing, a chemical vapor deposition process or other appropriate processes. The crystal shape of the formed semiconductor light-emitting layer 350 can meet the requirements of LED in application via the diamond film 350 serves as the substrate of the crystal growth, or a buffer layer can be formed on the diamond film in advance to eliminate the lattice mismatch. The heat dissipation efficiency of the LED 360 can be improved by the high heat-conductive layer 150 directly contacts with the diamond film 350, simultaneously.

If the formed LED 360 adopts a sapphire substrate or silicon substrate as a substrate 320, the substrate 320 usually has poor heat conductibility. At this time, although the diamond film 350 can be effectively transmitted the heat generated by semiconductor light-emitting layer 330, the heat dissipation efficiency of the LED 360 is affected by limiting the substrate 320 with poor heat conductibility. In this situation, the substrate 320 as shown in FIG. 3B can be further removed to enhance the contact between the diamond film 350 and air or other heat dissipation media and improve the heat dissipation efficiency of the LED, as shown in FIG. 3C. The method of removing the substrate can be, for example, an etching process or a laser ablation process.

Certainly, it is alternative to choose the method of grinding the substrate to enhance the heat dissipation efficiency of the LED.

Although the present invention has been disclosed above by the embodiments, they are not intended to limit the present invention. Anybody skilled in the art can make some modifications and alterations without departing from the spirit and scope of the present invention. Therefore, the protecting range of the present invention falls in the appended claims.

What is claimed is:

1. A manufacturing method of a light-emitting diode (LED), comprising:
providing a semiconductor structure having a sapphire substrate and a semiconductor light-emitting layer, wherein a first surface of the semiconductor light-emitting layer covers and contacts with the sapphire substrate;
fixing the semiconductor structure on a supported base;
Removing the sapphire substrate;
forming a high heat-conductive layer on the first surface of the semiconductor light-emitting layer; and
removing the supported base.

2. The manufacturing method of the LED as claimed in claim 1, wherein the high heat-conductive layer is a film with a coefficient of thermal conductivity larger than 2 W/cm.k.

3. The manufacturing method of the LED as claimed in claim 1, wherein the high heat-conductive layer is a diamond film.

4. The manufacturing method of the LED as claimed in claim 3, wherein the step of forming the diamond film is a chemical vapor deposition process.

5. The manufacturing method of the LED as claimed in claim 1, wherein the step of removing the sapphire substrate is an etching process or a laser ablation process.

6. The manufacturing method of the LED as claimed in claim 1, wherein the semiconductor light-emitting layer comprises a N-type semiconductor layer and a P-type semiconductor layer.

7. A manufacturing method of a light-emitting diode (LED), comprising:
providing a semiconductor structure having a sapphire substrate and a semiconductor light-emitting layer, wherein a surface of the semiconductor light-emitting layer covers and contacts with the sapphire substrate;
fixing the semiconductor structure on a supported base;
grinding the sapphire substrate so that a thickness of the sapphire substrate is between 0 micrometer to 50 micrometers;
forming a high heat-conductive layer on the surface of the grinded sapphire substrate; and
removing the supported base.

8. The manufacturing method of the LED as claimed in claim 7, wherein the high heat-conductive layer is a film with a coefficient of thermal conductivity larger than 2 W/cm.k.

9. The manufacturing method of the LED as claimed in claim 7, wherein the high heat-conductive layer is a diamond film.

10. The manufacturing method of the LED as claimed in claim 9, wherein the step of forming the diamond film is a chemical vapor deposition process.

11. The manufacturing method of the LED as claimed in claim 7, wherein the step of grinding the sapphire substrate is an etching process or a laser ablation process.

12. The manufacturing method of the LED as claimed in claim 7, wherein the semiconductor light-emitting layer comprises a N-type semiconductor layer and a P-type semiconductor layer, and the N-type semiconductor layer and the P-type semiconductor layer are stacked on the sapphire substrate.

13. A manufacturing method of a light-emitting diode (LED), comprising:
providing a substrate;
forming a diamond film on the substrate; and
forming a semiconductor light-emitting layer on the diamond film, wherein the semiconductor light-emitting layer comprises a N-type semiconductor layer and a P-type semiconductor layer, and the N-type semiconductor layer and the P-type semiconductor layer are stacked on the diamond film.

14. The manufacturing method of the LED as claimed in claim 13, wherein the substrate is selected from a group consisting of silicon substrate, aluminum oxide substrate, silicon nitride substrate, sapphire substrate and silicon carbide substrate.

15. The manufacturing method of the LED as claimed in claim 13, further comprising removing the substrate to enhance the contact area between the diamond film and the heat dissipation media and improve the effect of the heat dissipation.

16. The manufacturing method of the LED as claimed in claim 15, wherein the step of removing the substrate is an etching process or a laser ablation process.

17. A light-emitting diode (LED), comprising:
a diamond film substrate; and
a semiconductor light-emitting layer located on the diamond film substrate, wherein the semiconductor light-emitting layer comprises a N-type semiconductor layer and a P-type semiconductor layer, and the N-type semiconductor layer or the P-type semiconductor layer contacts the diamond film substrate.

18. The LED as claimed in claim 17, wherein the material of the semiconductor light-emitting layer is selected from one group consisting of gallium nitride (GaN), aluminum gallium nitride (AlGaN), indium gallium nitride (InGaN), gallium arsenide (GaAs), gallium phosphide (GaP), aluminum gallium arsenide (AlGaAs), aluminum indium gallium phosphida (AlInGaP), zinc selenide (ZnSe) and silicon carbide (SiC).

19. A light-emitting diode (LED), comprising:
a sapphire substrate, wherein the thickness of the sapphire substrate is between 0 micrometer to 50 micrometers;
a semiconductor light-emitting layer located on the sapphire substrate, wherein the semiconductor light-emitting layer comprises a N-type semiconductor layer and a P-type semiconductor layer, and the N-type semiconductor layer or the P-type semiconductor layer contacts the sapphire substrate; and
a diamond film located on a surface of the semiconductor light-emitting layer which is opposite to the sapphire substrate.

20. The LED as claimed in claim 19, wherein the material of the semiconductor light-emitting layer is selected from one group consisting of gallium nitride (GaN), aluminum gallium nitride (AlGaN), indium gallium nitride (InGaN), gallium arsenide (GaAs), gallium phosphide (GaP), aluminum gallium arsenide (AlGaAs), aluminum indium gallium phosphida (AlInGaP), zinc selenide (ZnSe) and silicon carbide (SiC).
